(19) United States
(12) Patent Application Publication
(10) Pub. No.: US 2021/0407919 A1
(43) Pub. Date: Dec. 30, 2021

(54) HYBRID METALLIZATION AND LAMINATE STRUCTURE

(71) Applicant: QUALCOMM Incorporated, San Diego, CA (US)

(72) Inventors: Aniket PATIL, San Diego, CA (US); Hong Bok WE, San Diego, CA (US); Brigham NAVAJA, San Diego, CA (US)

(21) Appl. No.: 16/915,199

(22) Filed: Jun. 29, 2020

(51) Int. Cl. H01L 23/538; H01L 23/31; H01L 23/00; H01L 21/48; H01L 21/56

(52) U.S. Cl. CPC H01L 23/5389; H01L 23/3128; H01L 23/5383; H01L 23/5386; H01L 23/562; H01L 2924/3511; H01L 24/20; H01L 21/4853; H01L 21/4857; H01L 21/565; H01L 2224/214; H01L 24/19

(57) ABSTRACT

Conventional package problems may be overcome with a hybrid metallization and laminate structure that avoids warpage problems and size reduction problems. One example structure may include a metallization structure directly attached to an active side of a logic die stack in a core substrate (on one or both sides of the substrate) with laminate layers built-up on top of the metallization structures for a symmetrical package structure.

### FIELD OF DISCLOSURE

This disclosure relates generally to integrated circuit (IC) packages, and more specifically, but not exclusively, to three dimensional (3D) IC packages.

### BACKGROUND

Modern electronics are becoming more prevalent as smaller electronics enable more applications for the small electronics. One of the basic components of modern electronics is the IC package. The IC package provides support, protection, and routing paths for the electronics in the IC package, such as logic die, semiconductor die, active devices, and passive devices. However, the constant demand to reduce or miniaturize the size or footprint of conventional IC packages has forced designed to turn to creative solutions.

One such solution is the 3D IC package. The 3D IC package allows improvement in the integration density of various electronic components (e.g., transistors, diodes, resistors, capacitors, etc.) without increasing the footprint of the package. This is achieved by increasing the height of the package (3^{rd} dimension, vertical z) without increasing the two dimensional (1^{st} and 2^{nd} dimensions, horizontal x and y) aspects (i.e., increasing the footprint).

Unfortunately, the demand for thinner (z dimension) and smaller package sizes (x and y dimensions) have created problems for conventional 3D IC packages and their features. Problems with such features as laminate substrates and metallization structures. Laminate substrates are good at warpage control, but have larger features and larger thicknesses. Metallization structures (e.g., redistribution structures or pathways, such as for routing signals into, within, and out of the structure) only IC packages have very fine feature sizes, preferred for routing, but warpage performance is not on par compared to laminate substrates.

Accordingly, there is a need for systems, apparatus, and methods that overcome the deficiencies of conventional approaches including the methods, system and apparatus provided hereby.

### SUMMARY

The following presents a simplified summary relating to one or more aspects and/or examples associated with the apparatus and methods disclosed herein. As such, the following summary should not be considered an extensive overview relating to all contemplated aspects and/or examples, nor should the following summary be regarded to identify key or critical elements relating to all contemplated aspects and/or examples or to delineate the scope associated with any particular aspect and/or example. Accordingly, the following summary has the sole purpose to present certain concepts relating to one or more aspects and/or examples relating to the apparatus and methods disclosed herein in a simplified form to precede the detailed description presented below.

In one aspect, a package comprises: a core; a first metallization structure on a first side of the core; a second metallization structure on a second side of the core opposite the first side; a first laminate layer on the first metallization structure opposite the core; a second laminate layer on the second metallization structure opposite the core; and a first device, the first device located in the core, on the first laminate layer opposite the first metallization structure, or on the second laminate layer opposite the second metallization structure.

In another aspect, a package comprises: a core; a first means for metallization on a first side of the core; a second means for metallization on a second side of the core opposite the first side; a first means for support on the first means for metallization opposite the core; a second means for support on the second means for metallization opposite the core; and a first device, the first device located in the core, on the first means for support opposite the first means for metallization, or on the second means for support opposite the second means for metallization.

In still another aspect, a method for manufacturing a package comprises: providing a core; forming a first metallization structure on a first side of the core; forming a second metallization structure on a second side of the core opposite the first side; forming a first laminate layer on the first metallization structure opposite the core; forming a second laminate layer on the second metallization structure opposite the core; and placing a first device in the core, on the first laminate layer opposite the first metallization structure, or on the second laminate layer opposite the second metallization structure.

In still another aspect, a non-transitory computer-readable medium comprising instructions that when executed by a processor cause the processor to perform a method, the method comprises: providing a core; forming a first metallization structure on a first side of the core; forming a second metallization structure on a second side of the core opposite the first side; forming a first laminate layer on the first metallization structure opposite the core; forming a second laminate layer on the second metallization structure opposite the core; and placing a first device in the core, on the first laminate layer opposite the first metallization structure, or on the second laminate layer opposite the second metallization structure.

Other features and advantages associated with the apparatus and methods disclosed herein will be apparent to those skilled in the art based on the accompanying drawings and detailed description.

### BRIEF DESCRIPTION OF THE DRAWINGS

A more complete appreciation of aspects of the disclosure and many of the attendant advantages thereof will be readily obtained as the same becomes better understood by reference to the following detailed description when considered in connection with the accompanying drawings which are presented solely for illustration and not limitation of the disclosure, and in which:

FIG. 1 illustrates an exemplary package in accordance with some examples of the disclosure;

FIGS. 2A-M illustrate an exemplary method for manufacturing a package in accordance with some examples of the disclosure;

FIG. 3 illustrates an exemplary partial method in accordance with some examples of the disclosure;

FIG. 4 illustrates an exemplary mobile device in accordance with some examples of the disclosure; and

FIG. 5 illustrates various electronic devices that may be integrated with any of the aforementioned methods, devices, semiconductor devices, integrated circuits, die, interposers, packages, or package-on-packages (PoPs) in accordance with some examples of the disclosure.

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

The exemplary methods, apparatus, and systems disclosed herein mitigate shortcomings of the conventional methods, apparatus, and systems, as well as other previously unidentified needs. For example, examples herein include a hybrid structure for IC packages (e.g., PoP, MCM, RF modules) that benefit from having both a metallization structure and laminate layers. In some examples, a structure may include a metallization structure build up on a back to back logic die stack and laminate layers (prepreg or glass fiber impregnated resin) built-up on top of these metallization structures. Examples herein may provide benefits over conventional packages by making the package/module structure symmetric as it includes laminate substrates on top of metallization structures or layers, metallization structures directly attached on top of logic die or similar components (especially on the active side of the die) making signal routing much more flexible with fine features. In addition, hybrid structures, such as detailed herein, overcome at least two issues with conventional 3D structures including warpage problems when using only a metallization layer concern due to RDL only layers and larger package sizes with design features size reduction problems. Thus, examples herein provide a hybrid package structure that allows thinner package sizes than conventional approaches, controlled warpage for the package, package form factor reduction, ability to use fine design features for die breakout regions, elimination of first level interconnect (no bumps for die), and improved signal integrity (SI) for high-speed input/output (HSIO) links and power integrity (PI) in power distribution networks (PDNs) for power rails.

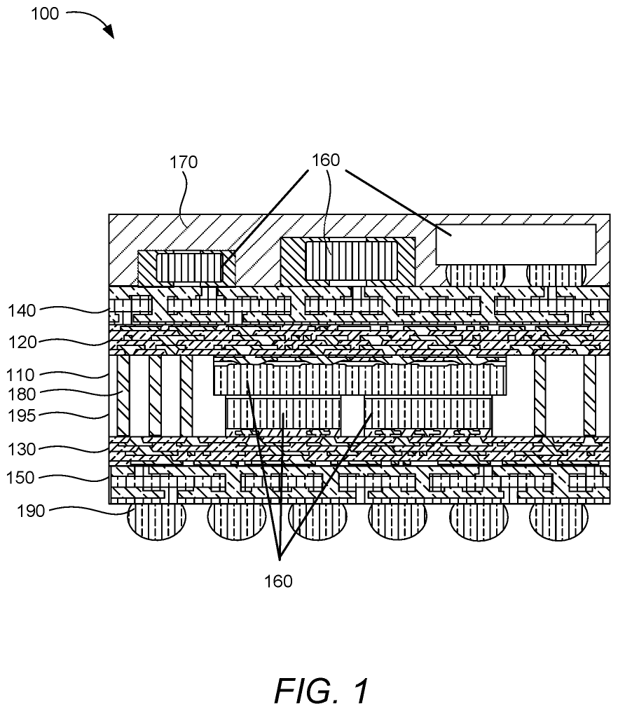

FIG. 1 illustrates an exemplary package in accordance with some examples of the disclosure. As shown in FIG. 1, a package 100 (e.g., a 3D semiconductor package or module) may include a core 110; a first metallization structure 120 (e.g., a structure with conductive metal that may be configured as signal pathways such as a redistribution layer) on a first side of the core 110; a second metallization structure 130 on a second side of the core opposite the first side; a first laminate layer 140 on the first metallization structure 120 opposite the core 110; a second laminate layer 150 on the second metallization structure 130 opposite the core 110; and at least a first device 160, the first device 160 may be located in the core 110, on the first laminate layer 140 opposite the first metallization structure 120, or on the second laminate layer 150 opposite the second metallization structure 130 (first device 160 on the second laminate layer 150 is not shown).

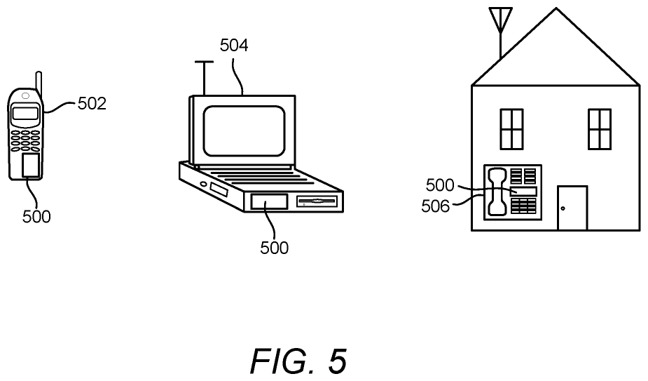

The package 100 may also include a mold compound 170 on the first laminate layer 140 opposite the first metallization structure 120; a plurality of vias 180 in the core 110; a plurality of external connections 190 (e.g., solder balls); and an encapsulant 195 encapsulating any devices in core 110 for example. The first device 160 may be a passive device, memory chip, logic die, integrated circuit or similar and may be attached to the first laminate layer 140 with surface mount technology, embedded in the core 110, using embedded trace substrate technology for example, or attached to the second laminate layer 150 (not shown) such as in a marsupial configuration within a perimeter of the external connections 190. The package 100 may also be incorporated into a device selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, and a device in an automotive vehicle (See FIG. 5, for example). It should be also understood that the devices and methods shown and described herein may omit descriptions and/or illustrations of conventional package assembly components or activities in the interest of brevity without prejudice or disclaimer.

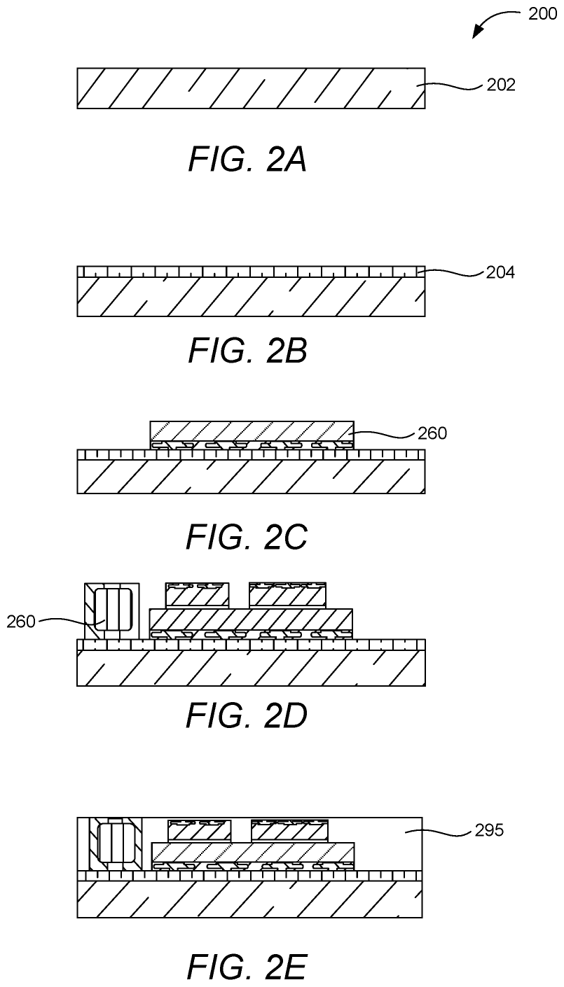

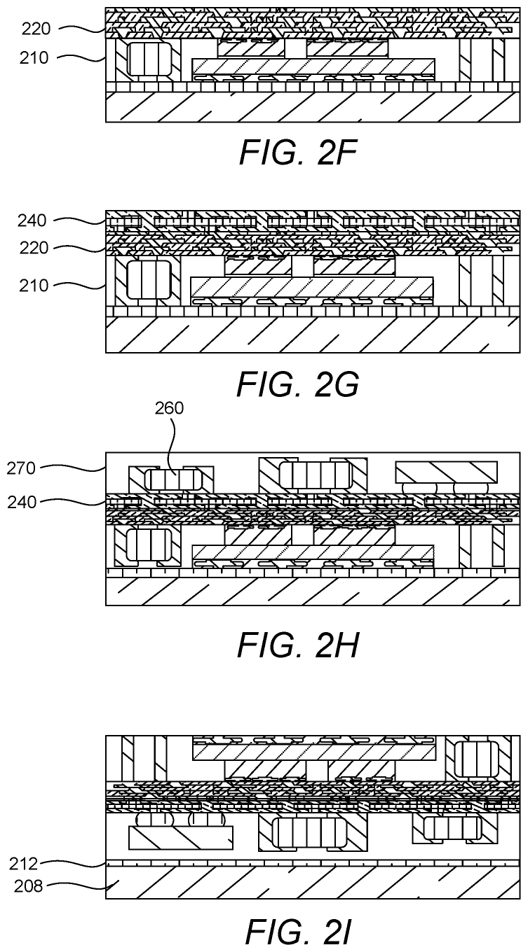

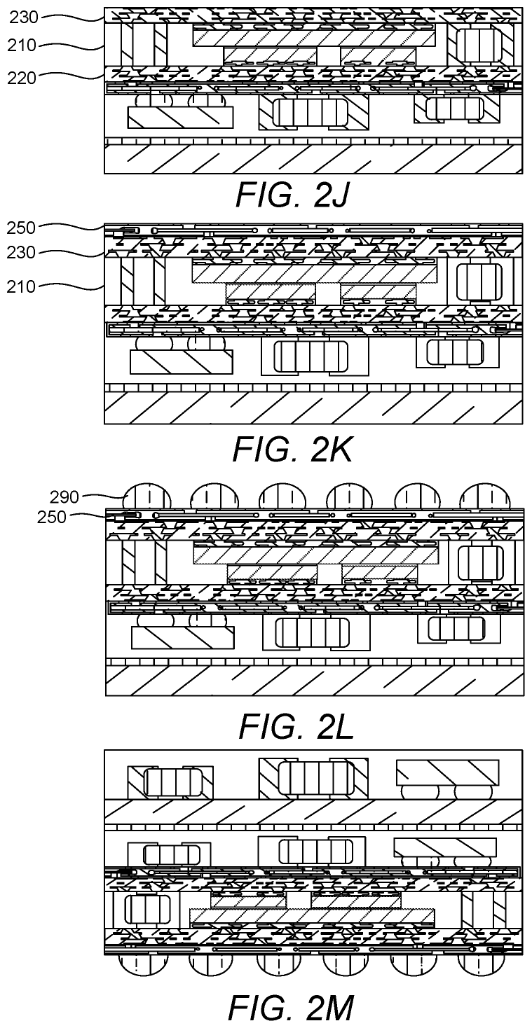

FIGS. 2A-M illustrate an exemplary partial method for manufacturing a package in accordance with some examples of the disclosure. As shown in FIG. 2A, a partial method 200 for manufacturing a package (e.g., package 100) may begin with providing a first carrier 202. As shown in FIG. 2B, the partial method 200 may continue with applying an adhesive coat 204 (e.g., a temporary bond film) to the first carrier 202. As shown in FIG. 2C, the partial method 200 may continue with attaching a first device 260 (e.g., first device 160) on or to the adhesive coat 204. As shown in FIG. 2D, the partial method 200 may optionally continue with attaching additional first devices 260 such as passive devices, memory chips, logic dice, integrated circuits or similar in various configurations and locations. As shown in FIG. 2E, the partial method 200 may continue with applying an encapsulant or mold 295 (e.g., encapsulant 195) and may include grinding and (not shown) forming a first step or portion of a contact, via or similar (e.g., via 180) in various configurations and locations.

As shown in FIG. 2F, the partial method 200 may continue with forming a first metallization structure 220 (e.g., first metallization structure 120) on first side of a core 210 (e.g., core 110) comprising the encapsulant 295 and first devices 260. As shown in FIG. 2G, the partial method 200 may continue with forming a first laminate layer 240 (e.g., first laminate layer 140) on the first metallization structure 220 opposite the core 210. As shown in FIG. 2H, the partial method 200 may continue with attaching first devices 260 to the first laminate layer 240 and applying an encapsulant or mold 270 (e.g., mold 170). As shown in FIG. 2I, the partial method 200 may continue with attaching a second carrier 208 with a second adhesive coat 212 to the mold 270 and rotating the structure.

As shown in FIG. 2J, the partial method 200 may continue with forming a second metallization structure 230 (e.g., second metallization structure 130) on a second side of the core 210 opposite the first metallization structure 220. As shown in FIG. 2K, the partial method 200 may continue with forming a second laminate layer 250 (e.g., second laminate layer 150) on the second metallization structure 230 opposite the core 210. As shown in FIG. 2L, the partial method 200 may continue with forming a plurality of external connections 290 (e.g., plurality of external connections 190) on the second laminate layer 250 (and optionally, other finishing processes such as surface treatment). As shown in FIG. 2M, the partial method 200 may conclude with removing the second carrier 208 (and optionally, singulation) to form a package (e.g., package 100).

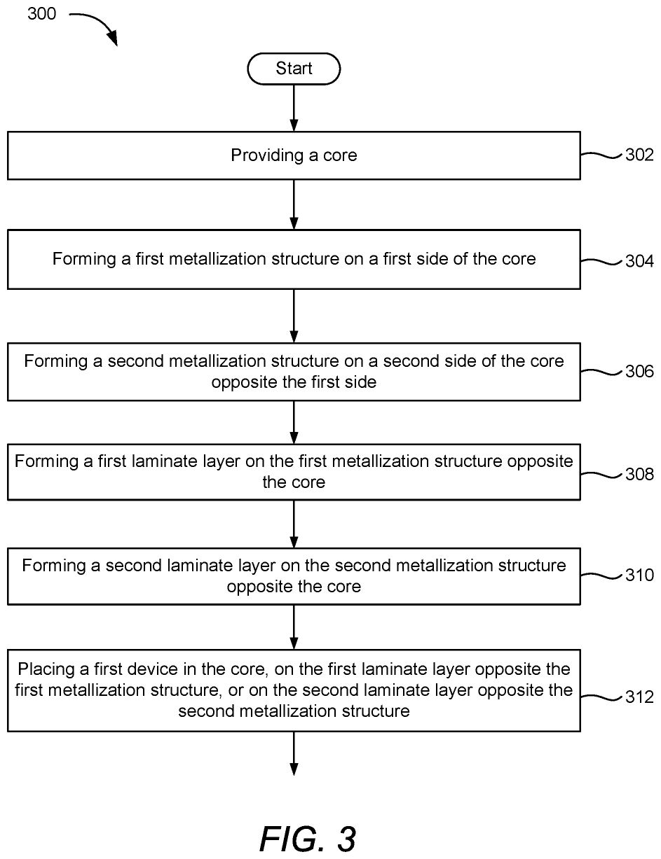

FIG. 3 illustrates an exemplary partial method in accordance with some examples of the disclosure. As shown in FIG. 3, the partial method 300 may begin in block 302 with providing a core. The partial method 300 may continue in block 304 with forming a first metallization structure on a first side of the core. The partial method 300 may continue in block 306 with forming a second metallization structure on a second side of the core opposite the first side. The partial method 300 may continue in block 308 with forming a first laminate layer on the first metallization structure opposite the core. The partial method 300 may continue in block 310 with forming a second laminate layer on the second metallization structure opposite the core. The partial method 300 may conclude in block 312 with placing a first device in the core, on the first laminate layer opposite the first metallization structure, or on the second laminate layer opposite the second metallization structure.

Alternatively, the partial method 300 may include forming a mold compound on the first laminate layer opposite the first metallization structure; forming a plurality of vias in the core; forming a plurality of external connections; and incorporating the transistor circuit into a device selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, and a device in an automotive vehicle. In addition, the partial method 300 may include wherein the plurality of external connections are solder balls; the first device is attached to the first laminate layer with surface mount technology; and the first device is attached to the second laminate layer within a plurality of solder balls configured in a land side grid array.

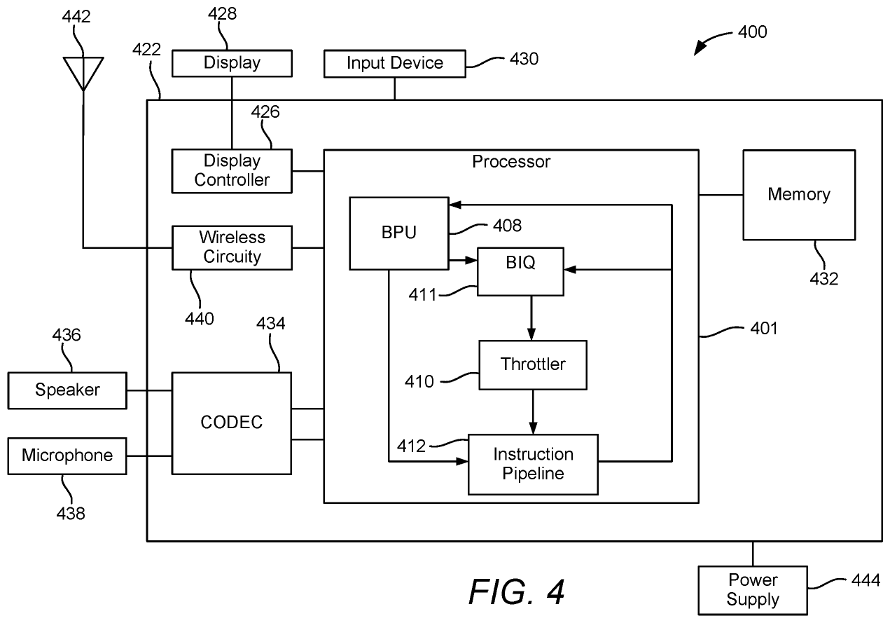

FIG. 4 illustrates an exemplary mobile device in accordance with some examples of the disclosure. Referring now to FIG. 4, a block diagram of a mobile device 400 that is configured according to one or more exemplary aspects. In some aspects, mobile device 400 may be configured as a wireless communication device. As shown, mobile device 400 includes processor 401, which may be configured to implement the methods described herein in some aspects. Processor 401 is shown to comprise instruction pipeline 412, buffer processing unit (BPU) 408, branch instruction queue (BIQ) 411, and throttler 410 as is well known in the art. Other well-known details (e.g., counters, entries, confidence fields, weighted sum, comparator, etc.) of these blocks have been omitted from this view of processor 401 for the sake of clarity.

Processor 401 may be communicatively coupled to memory 432 over a link, which may be a die-to-die or chip-to-chip link. Mobile device 400 also include display 428 and display controller 426, with display controller 426 coupled to processor 401 and to display 428.

In some aspects, FIG. 4 may include coder/decoder (CODEC) 434 (e.g., an audio and/or voice CODEC) coupled to processor 401; speaker 436 and microphone 438 coupled to CODEC 434; and wireless controller 440 (which may include a modem) coupled to wireless antenna 442 and to processor 401.

In a particular aspect, where one or more of the above-mentioned blocks are present, processor 401, display controller 426, memory 432, CODEC 434, and wireless controller 440 can be included in a system-in-package or system-on-chip device 422. Input device 430 (e.g., physical or virtual keyboard), power supply 444 (e.g., battery), display 428, input device 430, speaker 436, microphone 438, wireless antenna 442, and power supply 444 may be external to system-on-chip device 422 and may be coupled to a component of system-on-chip device 422, such as an interface or a controller.

It should be noted that although FIG. 4 depicts a mobile device, processor 401 and memory 432 may also be integrated into a set top box, a music player, a video player, an entertainment unit, a navigation device, a personal digital assistant (PDA), a fixed location data unit, a computer, a laptop, a tablet, a communications device, a mobile phone, or other similar devices.

FIG. 5 illustrates various electronic devices that may be integrated with any of the aforementioned integrated device, semiconductor device, integrated circuit, die, interposer, package or package-on-package (PoP) in accordance with some examples of the disclosure. For example, a mobile phone device 502, a laptop computer device 504, and a fixed location terminal device 506 may include an integrated device 500 as described herein. The integrated device 500 may be, for example, any of the integrated circuits, dies, integrated devices, integrated device packages, integrated circuit devices, device packages, integrated circuit (IC) packages, package-on-package devices described herein. The devices 502, 504, 506 illustrated in FIG. 5 are merely exemplary. Other electronic devices may also feature the integrated device 500 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), or any other device that stores or retrieves data or computer instructions, or any combination thereof.

It will be appreciated that various aspects disclosed herein can be described as functional equivalents to the structures, materials and/or devices described and/or recognized by those skilled in the art. It should furthermore be noted that methods, systems, and apparatus disclosed in the description or in the claims can be implemented by a device comprising means for performing the respective actions of this method. For example, in one aspect, a package may comprise: a core; a first means for metallization (e.g., first metallization structure) on a first side of the core; a second means for metallization (e.g., second metallization structure) on a second side of the core opposite the first side; a first means for support (e.g., first laminate layer) on the first means for metallization opposite the core; a second means for support (e.g., second laminate layer) on the second means for metallization opposite the core; and a first device, the first device located in the core, on the first means for support opposite the first means for metallization, or on the second means for support opposite the second means for metallization. It will be appreciated that the aforementioned aspects are merely provided as examples and the various aspects claimed are not limited to the specific references and/or illustrations cited as examples.

One or more of the components, processes, features, and/or functions illustrated in FIGS. 1-5 may be rearranged and/or combined into a single component, process, feature or function or incorporated in several components, processes, or functions. Additional elements, components, processes, and/or functions may also be added without departing from the disclosure. It should also be noted that FIGS. 1-5 and its corresponding description in the present disclosure is not limited to dies and/or ICs. In some implementations, FIGS. 1-5 and its corresponding description may be used to manufacture, create, provide, and/or produce integrated devices. In some implementations, a device may include a die, an integrated device, a die package, an integrated circuit (IC), a device package, an integrated circuit (IC) package, a wafer, a semiconductor device, a package on package (PoP) device, and/or an interposer. An active side of a device, such as a die, is the part of the device that contains the active components of the device (e.g. transistors, resistors, capacitors, inductors etc.), which perform the operation or function of the device. The backside of a device is the side of the device opposite the active side. As used herein, a metallization structures may include metal layers, vias, pads, or traces with dielectric between, such as a redistribution layer or RDL).

As used herein, the terms “user equipment” (or “UE”), “user device,” “user terminal,” “client device,” “communication device,” “wireless device,” “wireless communications device,” “handheld device,” “mobile device,” “mobile terminal,” “mobile station,” “handset,” “access terminal,” “subscriber device,” “subscriber terminal,” “subscriber station,” “terminal,” and variants thereof may interchangeably refer to any suitable mobile or stationary device that can receive wireless communication and/or navigation signals. These terms include, but are not limited to, a music player, a video player, an entertainment unit, a navigation device, a communications device, a smartphone, a personal digital assistant, a fixed location terminal, a tablet computer, a computer, a wearable device, a laptop computer, a server, an automotive device in an automotive vehicle, and/or other types of portable electronic devices typically carried by a person and/or having communication capabilities (e.g., wireless, cellular, infrared, short-range radio, etc.). These terms are also intended to include devices which communicate with another device that can receive wireless communication and/or navigation signals such as by short-range wireless, infrared, wire line connection, or other connection, regardless of whether satellite signal reception, assistance data reception, and/or position-related processing occurs at the device or at the other device. In addition, these terms are intended to include all devices, including wireless and wire line communication devices, that are able to communicate with a core network via a radio access network (RAN), and through the core network the UEs can be connected with external networks such as the Internet and with other UEs. Of course, other mechanisms of connecting to the core network and/or the Internet are also possible for the UEs, such as over a wired access network, a wireless local area network (WLAN) (e.g., based on IEEE 802.11, etc.) and so on. UEs can be embodied by any of a number of types of devices including but not limited to printed circuit (PC) cards, compact flash devices, external or internal modems, wireless or wire line phones, smartphones, tablets, tracking devices, asset tags, and so on. A communication link through which UEs can send signals to a RAN is called an uplink channel (e.g., a reverse traffic channel, a reverse control channel, an access channel, etc.). A communication link through which the RAN can send signals to UEs is called a downlink or forward link channel (e.g., a paging channel, a control channel, a broadcast channel, a forward traffic channel, etc.). As used herein the term traffic channel (TCH) can refer to an uplink/reverse or downlink/forward traffic channel.

The wireless communication between electronic devices can be based on different technologies, such as code division multiple access (CDMA), W-CDMA, time division multiple access (TDMA), frequency division multiple access (FDMA), Orthogonal Frequency Division Multiplexing (OFDM), Global System for Mobile Communications (GSM), 3GPP Long Term Evolution (LTE), Bluetooth (BT), Bluetooth Low Energy (BLE), IEEE 802.11 (WiFi), and IEEE 802.15.4 (Zigbee/Thread) or other protocols that may be used in a wireless communications network or a data communications network. Bluetooth Low Energy (also known as Bluetooth LE, BLE, and Bluetooth Smart) is a wireless personal area network technology designed and marketed by the Bluetooth Special Interest Group intended to provide considerably reduced power consumption and cost while maintaining a similar communication range. BLE was merged into the main Bluetooth standard in 2010 with the adoption of the Bluetooth Core Specification Version 4.0 and updated in Bluetooth 5 (both expressly incorporated herein in their entirety).

The word “exemplary” is used herein to mean “serving as an example, instance, or illustration.” Any details described herein as “exemplary” is not to be construed as advantageous over other examples. Likewise, the term “examples” does not mean that all examples include the discussed feature, advantage or mode of operation. Furthermore, a particular feature and/or structure can be combined with one or more other features and/or structures. Moreover, at least a portion of the apparatus described hereby can be configured to perform at least a portion of a method described hereby.

The terminology used herein is for the purpose of describing particular examples and is not intended to be limiting of examples of the disclosure. As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, actions, operations, elements, and/or components, but do not preclude the presence or addition of one or more other features, integers, actions, operations, elements, components, and/or groups thereof.

It should be noted that the terms “connected,” “coupled,” or any variant thereof, mean any connection or coupling, either direct or indirect, between elements, and can encompass a presence of an intermediate element between two elements that are “connected” or “coupled” together via the intermediate element.

Any reference herein to an element using a designation such as “first,” “second,” and so forth does not limit the quantity and/or order of those elements. Rather, these designations are used as a convenient method of distinguishing between two or more elements and/or instances of an element. Also, unless stated otherwise, a set of elements can comprise one or more elements.

Nothing stated or illustrated depicted in this application is intended to dedicate any component, action, feature, benefit, advantage, or equivalent to the public, regardless of whether the component, action, feature, benefit, advantage, or the equivalent is recited in the claims.

The methods, sequences and/or algorithms described in connection with the examples disclosed herein may be incorporated directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art including non-transitory types of memory or storage mediums. An exemplary storage medium is coupled to the processor such that the processor can read information from, and write information to, the storage medium. In the alternative, the storage medium may be integral to the processor.

In the detailed description above it can be seen that different features are grouped together in examples. This manner of disclosure should not be understood as an intention that the claimed examples have more features than are explicitly mentioned in the respective claim. Rather, the disclosure may include fewer than all features of an individual example disclosed. Therefore, the following claims should hereby be deemed to be incorporated in the description, wherein each claim by itself can stand as a separate example. Although each claim by itself can stand as a separate example, it should be noted that—although a dependent claim can refer in the claims to a specific combination with one or a plurality of claims—other examples can also encompass or include a combination of said dependent claim with the subject matter of any other dependent claim or a combination of any feature with other dependent and independent claims. Such combinations are proposed herein, unless it is explicitly expressed that a specific combination is not intended. Furthermore, it is also intended that features of a claim can be included in any other independent claim, even if said claim is not directly dependent on the independent claim.

Furthermore, in some examples, an individual action can be subdivided into a plurality of sub-actions or contain a plurality of sub-actions. Such sub-actions can be contained in the disclosure of the individual action and be part of the disclosure of the individual action.

While the foregoing disclosure shows illustrative examples of the disclosure, it should be noted that various changes and modifications could be made herein without departing from the scope of the disclosure as defined by the appended claims. The functions and/or actions of the method claims in accordance with the examples of the disclosure described herein need not be performed in any particular order. Additionally, well-known elements will not be described in detail or may be omitted so as to not obscure the relevant details of the aspects and examples disclosed herein. Furthermore, although elements of the disclosure may be described or claimed in the singular, the plural is contemplated unless limitation to the singular is explicitly stated.

What is claimed is:

1. A package comprising:
a core;
a first metallization structure on a first side of the core;
a second metallization structure on a second side of the core opposite the first side;
a first laminate layer on the first metallization structure opposite the core;
a second laminate layer on the second metallization structure opposite the core; and
a first device, the first device located in the core, on the first laminate layer opposite the first metallization structure, or on the second laminate layer opposite the second metallization structure.

2. The package of claim 1, further comprising a mold compound on the first laminate layer opposite the first metallization structure.

3. The package of claim 1, further comprising a plurality of vias in the core.

4. The package of claim 1, further comprising a plurality of external connections.

5. The package of claim 4, wherein the plurality of external connections are solder balls.

6. The package of claim 1, wherein the first device is attached to the first laminate layer with surface mount technology.

7. The package of claim 1, wherein the first device is attached to the second laminate layer within a plurality of solder balls configured in a land side grid array.

8. The package of claim 1, wherein package is incorporated into a device selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, and a device in an automotive vehicle.

9. A package comprising:
a core;
a first means for metallization on a first side of the core;
a second means for metallization on a second side of the core opposite the first side;
a first means for support on the first means for metallization opposite the core;
a second means for support on the second means for metallization opposite the core; and
a first device, the first device located in the core, on the first means for support opposite the first means for metallization, or on the second means for support opposite the second means for metallization.

10. The package of claim 9, further comprising a mold compound on the first means for support opposite the first means for metallization.

11. The package of claim 9, further comprising a plurality of vias in the core.

12. The package of claim 9, further comprising a plurality of external connections.

13. The package of claim 12, wherein the plurality of external connections are solder balls.

14. The package of claim 9, wherein the first device is attached to the first means for support with surface mount technology.

15. The package of claim 9, wherein the first device is attached to the second means for support within a plurality of solder balls configured in a land side grid array.

16. The package of claim 9, wherein package is incorporated into a device selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, and a device in an automotive vehicle.

17. A method for manufacturing a package, the method comprising:
providing a core;
forming a first metallization structure on a first side of the core;
forming a second metallization structure on a second side of the core opposite the first side;
forming a first laminate layer on the first metallization structure opposite the core;
forming a second laminate layer on the second metallization structure opposite the core; and
placing a first device in the core, on the first laminate layer opposite the first metallization structure, or on the second laminate layer opposite the second metallization structure.

18. The method of claim 17, further comprising forming a mold compound on the first laminate layer opposite the first metallization structure.

19. The method of claim 17, further comprising forming a plurality of vias in the core.

20. The method of claim 17, further comprising forming a plurality of external connections.

21. The method of claim 20, wherein the plurality of external connections are solder balls.

22. The method of claim 17, wherein the first device is attached to the first laminate layer with surface mount technology.

23. The method of claim 17, wherein the first device is attached to the second laminate layer within a plurality of solder balls configured in a land side grid array.

24. The method of claim 17, further comprising incorporating the package into a device selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, and a device in an automotive vehicle.

25. A non-transitory computer-readable medium comprising instructions that when executed by a processor cause the processor to perform a method, the method comprising:
providing a core;
forming a first metallization structure on a first side of the core;
forming a second metallization structure on a second side of the core opposite the first side;
forming a first laminate layer on the first metallization structure opposite the core;
forming a second laminate layer on the second metallization structure opposite the core; and
placing a first device in the core, on the first laminate layer opposite the first metallization structure, or on the second laminate layer opposite the second metallization structure.

26. The non-transitory computer-readable medium of claim 25, wherein the method further comprises forming a mold compound on the first laminate layer opposite the first metallization structure.

27. The non-transitory computer-readable medium of claim 25, wherein the method further comprises forming a plurality of vias in the core.

28. The non-transitory computer-readable medium of claim 25, wherein the method further comprises forming a plurality of external connections.

29. The non-transitory computer-readable medium of claim 25, wherein the method further comprises attaching the first device to the first laminate layer with surface mount technology or attaching the first device to the second laminate layer within a plurality of solder balls configured in a land side grid array.

30. The non-transitory computer-readable medium of claim 25, wherein the method further comprises incorporating the package into a device selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, and a device in an automotive vehicle.
